(19) United States
(12) Patent Application Publication
(10) Pub. No.: US 2012/0305502 A1
(43) Pub. Date: Dec. 6, 2012

(54) ELECTRONIC DEVICE STAND WITH KEYBOARD ATTACHMENT

(75) Inventor: Daniel J. Haarburger, Boulder, CO (US)

(73) Assignee: Ethic LLC, Boulder, CO (US)

(21) Appl. No.: 13/470,094

(22) Filed: May 11, 2012

Related U.S. Application Data
(60) Provisional application No. 61/493,921, filed on Jun. 6, 2011.

(51) Int. Cl. H05K 7/18

(52) U.S. Cl. 211/26

(57) ABSTRACT

The disclosed technology includes a portable stand for planar displays or surfaces such as tablets, cellular phones, and other electronic devices that supports the display such that it is consistent with a user's line of sight. One embodiment includes two complementary components and has the utility to function independently as a stand that can be quickly and easily assembled, or as an attachment that can be connected to a data input device such as a wireless keyboard to unite the display and the input device into a single functioning unit. One embodiment provides an independent stand that is adaptable to service devices of varying dimensions, portable for mobile use, economical to produce and purchase, and compact such that it may be readily shipped or stored.

### CROSS-REFERENCE TO RELATED APPLICATION(S)

This patent application claims the benefit under 35 U.S.C. §119 of U.S. Provisional Patent Application No. 61/493,921, filed on 6 Jun. 2011, entitled “Electronic Device Stand with Keyboard Attachment Capability,” which is incorporated herein in its entirety by reference.

### BACKGROUND

Portable electronic devices are popular solutions to the computing and entertainment needs of many individuals. Just as laptop computers displaced desktop computers in the personal computing market, tablets and handheld electronic devices are displacing laptops because, for example, similar functionality may be obtained at a fraction of the size and price. The compact design of conventional tablets, cellular phones, and other portable electronic devices, however, may not offer the same utility as laptop computers when it comes to displaying and/or inputting data.

Conventional data input devices are frequently limited in their coupling functionality with portable electronic devices, have limited portability themselves, and/or fail to include a stand for positioning a portable electronic device. Conventional stands frequently can support only one or a limited number of models of devices, may also have limited portability themselves, and/or fail to include a data input device.

### BRIEF DESCRIPTION OF THE DRAWINGS

The accompanying drawings, which are incorporated herein and constitute part of this specification, illustrate exemplary embodiments of the invention, and, together with the general description given above and the detailed description given below, serve to explain the features, principles, and methods of the invention.

FIG. 1 is a right-side view illustrating an embodiment according to the present disclosure of a portable electronic device stand with a keyboard attachment.

FIG. 2 is a rear, top, right isometric view illustrating an embodiment according to the present disclosure of the two components of the stand shown in FIG. 1. The two components are shown in a decoupled arrangement.

FIG. 3 is a rear, top, left isometric view of the two components of the stand shown in FIG. 2. The two components are shown in the decoupled arrangement.

FIG. 4 is a rear, top, right isometric view of the two components of the stand shown in FIG. 2. The two components are shown in a coupled arrangement.

FIG. 5 is a right side view illustrating the stand shown in FIG. 1 receiving a handheld electronic device. The device is shown in broken line.

FIG. 6 is a right side, rear, top isometric view of the stand and device shown in FIG. 5.

FIG. 7 is a view similar to FIG. 6 except that the device is repositioned.

FIG. 8 is a front, top, left isometric view illustrating the stand shown in FIG. 1 supporting a cellular telephone.

FIG. 9 is a right side view illustrating the stand shown in FIG. 1 receiving a handheld electronic device and engaging a wireless keyboard. The device and the keyboard are shown in broken line.

FIG. 10 is a top, front, left isometric view illustrating the stand shown in FIG. 1 receiving a handheld cellular telephone and engaging a wireless keyboard. The telephone and the keyboard are shown in broken line.

FIG. 11 is a view similar to FIG. 10 except that the telephone is repositioned.

FIG. 12A is a perspective view and FIG. 12B is a side view of an embodiment of the present disclosure.

In the figures, the thickness and configuration of components may be exaggerated for clarity. The same reference numerals in different figures represent the same component. The broken lines in the figures are for illustrative purposes only.

### DETAILED DESCRIPTION

The following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be, but not necessarily are, references to the same embodiment; and, such references mean at least one of the embodiments.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way.

Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any exemplified term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions will control.

The disclosed technology relates to planar display devices such as tablets, cellular phones, and other portable electronics that may but are not required to contain a data storage function. More particularly, the technology relates to an apparatus such as a portable stand for such devices and a means of integrating those devices with independent tools for the input of data such as a wireless keyboard.

Portable electronic devices are becoming popular solutions to the computing and entertainment needs of many individuals. Just as laptop computers displaced desktop computers in the personal computing market, today handheld electronic devices and portable tablet computers are displacing laptops because they offer the same functionality at a fraction of the size and price. However, as a result of their compact design, tablets, smartphones, and other portable electronic devices do not offer the same utility as laptop computers when it comes to standalone information display and effective data input.

In order to offer an enhanced experience in these two areas a series of products have emerged that facilitate either the input or display of information. However none do both in a portable, compact, and inexpensive manner.

When it comes to inputting information, existing products are device exclusive. They do not offer portability and often fail to account for the display positioning of the electronic device in use. The Apple IPad Keyboard Dock™, for instance, offers an effective means of typing information into an IPad™ tablet, but it is not portable and does not function with smartphones, eReaders, or most other display devices. Conversely, the Apple Wireless Keyboard™ is portable and can be used with most Bluetooth enabled devices. It does not, however, secure the device in place so its information can be effectively displayed. Other wireless keyboards suffer the same issue—not securing the electronic device while in use, thus making it difficult to view or display information as it is input.

On the opposite end of the spectrum, other products do secure their corresponding electronic devices, yet these too are often exclusive to a single product, are rarely portable, and do not offer a system for effective information input. The Mini IPad Stand by LapWorks (http://www.laptopdesk.net/ipad-tablet-ereader-stands.html#paging) holds an electronic device upright so its information can be displayed but it does not integrate with keyboards or other devices in order to input information. Furthermore, its design is optimized for current Apple brand products and cannot be easily adapted to new devices or those of a different manufacturer. Other stands like the BookGem IPad Holder serve the function of displaying information but consume a significant amount of space. BookGem stands, much like those of other industry competitors, are not portable, do not function with devices other than tablets and e-readers, and cannot be effectively integrated with wireless keyboards or other data input devices.

Existing products in the market for portable electronic accessories are costly both to sell and manufacture. While some products may serve a variety of functions, the intricacy of their design, the quantity of their components, and the systems by which they are manufactured makes them costly to produce, easy to damage, and difficult to ship and store.

One embodiment of the disclosed apparatus provides hands free interactivity with an otherwise handheld device by offering a portable and adaptable stand for upright display. In addition, it offers the ability to manifest the desktop experience ad hoc by integrating such devices with peripherals like a data input device or wireless keyboard. In one embodiment, the apparatus derives its utility from its portable nature, its adaptability to a wide array of devices, and its unimposing design that enables easy storage and cost effective manufacturing.

One embodiment of the present technology acts as an independent stand for information display and one integrated with peripherals such as a data input device is based upon the recognition that many electronic devices are most effective when used in an upright position. In the case of tablets and e-readers, many personal computing devices are used most often for information display. In these circumstances, the user is not actively interacting with the device but instead engages passively, as would be the case when reading, viewing, or listening to media.

The disclosed technology enhances the user's experience by holding a device upright and at an angle consistent with the user's line of sight. One embodiment consists of two mirror components that function in unison to hold a device upright. By creating rear support for the device, the disclosed technology increases stability thus enabling increasing interaction with the device. Similarly, one embodiment of the disclosed apparatus fans out at the front, creating a wider base for increased lateral stability while maintaining a compact design for reasons of storage and portability. This compactness is enhanced by a set of circular extrusions on one component and corresponding holes on its complement that snap together so both components may be connected into a single unit.

Further, the low profile design of the apparatus does not obstruct the device's display, lending an enhanced viewing experience. Its rounded edges better enables a user to attach a device so it may be held up for use. The enlarged slot into which the device fits also simplifies this setup process, while simultaneously enabling the use of devices that may vary in dimension. Furthermore, the physical size of the apparatus and the means by which its components connect offers both portability and compact storage.

Additional utility is derived from the apparatus's ability to connect a display device with peripherals—including those for data input like a wireless keyboard. For example, the hook shaped cutout at the base of one of the disclosed embodiments slides on to the battery chamber of a wireless keyboard (e.g., an Apple wireless keyboard). Thus the keyboard and the display device are connected for simultaneous use. If the user prefers to interact with the said device independently, however, they retain the option to remove it vertically from the stand or detach the keyboard by sliding the clips off laterally.

One embodiment of the apparatus provides an adaptable device stand with integrative capability that is low cost to produce and substantially flat when not in use. Thus it is easily shipped and stored. The technology is optimized to be injection molded in a single step process thus eliminating the need for complex tooling and multiple stages in the manufacturing process.

An embodiment of the disclosed apparatus can enhance a user's experience reading information presented on a display of a portable electronic device and inputting data to the device. An approximately upright position of the device in one embodiment orients the display in a manner that is convenient for the user to read the data. Moreover, the stand is portable, compact, easily stored, and inexpensive to manufacture.

The disclosed apparatus provides hands-free interactivity with an otherwise handheld device. Moreover, the stand is configured to be coupled with a wide array of peripheral devices such as a wireless keyboard or other data input devices.

An embodiment of a stand according to the present disclosure includes two independent components that work in unison to hold a device approximately upright. A rear support for the device increases stability, thus enabling user interaction with the device; for example, engaging the device. The stand positions the device so as to orient the data display at an angle that is conducive for viewing data on the display; for example, orienting the data display approximately perpendicular to a user's line of sight. At its front, the stand may fan out creating a wider base for increased lateral stability while maintaining a compact design for storage and portability. This compactness may be enhanced by including mating features (e.g., extrusions and holes) on the two components that snap together so both components may be coupled into a single unit. Other coupling mechanisms can also be used, such as pivoting or hinging the units together, or using telescoping or sliding rods.

In one embodiment, three or more independent components can be used together to hold the device, and the three or more components can be held together using mating features or coupling mechanisms when not in use. Alternatively, an embodiment of the present disclosure is a single unit that is long enough to stably support the device.

An embodiment of a stand according to the present disclosure is configured to avoid obstructing a portable electronic device's data display and to facilitate coupling to the device. The stand's configuration includes a slot that is sized and shaped for releasably receiving devices that may vary in dimension. The stand's configuration also includes a fitting for releasably engaging a peripheral device. The fitting may, for example, slide onto a battery chamber of a wireless keyboard. Accordingly, the keyboard and the display device are coupled to be used together.

An embodiment of a stand according to the present disclosure allows independent interaction with one of a portable electronic device and a peripheral device. For example, the portable electronic device may be removed from the stand without disengaging the peripheral device, or the peripheral device may be disengaged from the stand without removing the portable electronic device from the stand.

Other enhancements for the stand can be incorporated into the embodiments of the present disclosure, such as using rubber or other slip-resistant pads on the portions of the stand that make contact with the supporting surface or on the slot that receives the electronic device or peripheral device.

Embodiments of stands according to the present disclosure may be molded, extruded using materials such as plastic or metal, cast, or otherwise machined or manufactured by other processes. Injection molding plastic in a single step process eliminates complex tooling and multiple stages in the manufacturing process. Other processes, e.g., assembling a plurality of pieces into an integrated unit, may also be used for embodiments according to the present disclosure. Examples of materials from which embodiments of the present disclosure can be made include, but are not limited to, aluminum, steel, brass, any metal, ABS (acrylonitrile butadiene styrene), polycarbonate, acrylic, any plastic, foam, rubber, wood, or resin. Further, any combination of materials can be used to manufacture embodiments of the present disclosure. Moreover, embodiments of the present disclosure can be produced to have any desired color or texture.

An embodiment of an apparatus according to the present disclosure supports a device, such as an electronic device, on a surface. The electronic device can include a processor and a display screen and is configured to be operably coupled to an input device. The apparatus includes first and second components. Each component includes a body; a device support portion coupled to the body and configured to receive an edge of the handheld device on a seat portion between a front arm and a back arm, wherein the handheld device is supported on a display side of the handheld device by the front arm and on a back side of the handheld device by the back arm; a front support member coupled to the body and configured to engage the surface, wherein the front support member has a suitable shape to receive an input device for the handheld device; and a back support member coupled to the body, the back arm, and the front support member, wherein the back support member is configured to engage the surface, wherein the first component and the second component are configured to be used together to support the handheld device in a suitable position for a user to view the display of the handheld device.

Optional features for the stand can also be included. For example, the slot receiving the electronic device can be placed on a pivot to allow a user to adjust the viewing angle. Alternatively or additionally, the slot can be adjusted to enable the stand to collapse or the screen of the device to fold onto the keyboard when not in use.

In one embodiment, the electronic device can be integrated into a protective case so that the stand can provide protection and a way to integrate with a third-party keyboard.

Further, one embodiment of the present disclosure provides an electronic connection to the electronic device. The electronic connection includes, but is not limited to, means for wired or wireless charging of the electronic device or other peripheral device(s), a memory function for storing data, additional processing abilities, and/or an electronic coupling between the electronic device and a keyboard or other peripheral for use with the device.

In one embodiment, the stand can also function as an electronic dock for the supported electronic device. For example, a keyboard, speakers, or other peripherals can couple to the stand through a USB port, Firewire, or other jack, and the information transferred by these peripherals are passed by the stand to the electronic display device. Thus, any type of peripheral to be used with the electronic display device can be electrically coupled to the display device through the stand. Electrical coupling can be in the form of one or more wires or cables, and the wires or cables can be housed at least partially within the stand. In one embodiment, the electrical coupling between the handheld device and the peripherals can be external to the stand, while the electrical coupling is physically coupled to the stand using an attachment mechanism.

One embodiment of the stand can include electronic peripherals including, but not limited to, speakers and/or lights.

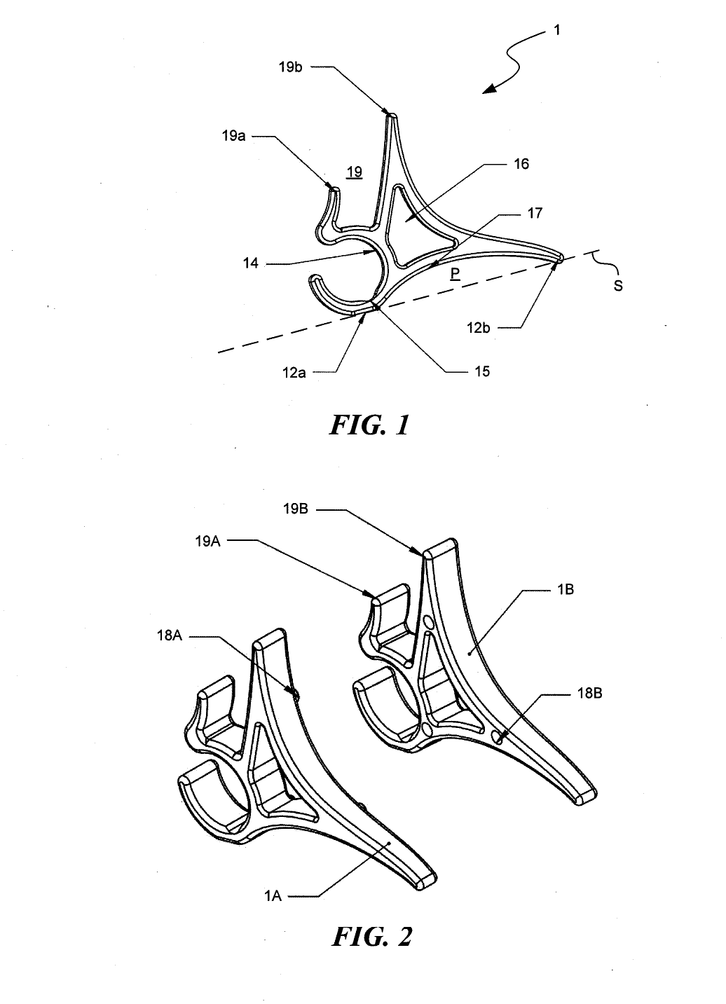

FIG. 1 illustrates a right side view of an electronic device stand 1 in accordance with the present invention. In this embodiment, the stand 1 is comprised of two freestanding components wherein a portable electronic device is inserted vertically into an angled slot at the top of each component. When inserted, the device is held in place by pivoting between a front retaining barrier 19a and a rear support 19b that define the slot. The rear support 19b extends higher than the front retaining barrier 19a. The slot can be made wider or narrower to accommodate devices having different thicknesses. Also, the angle of the slot can be manufactured to accommodate different viewing angles.

The downward force applied by the weight of the inserted device is transferred to a first contact point 12a disposed towards the front of the component and a second contact point 12b disposed approximately rearward of the device to stabilize the entire unit. The arc 17 that connects first and second points 12a, 12b defines in part a passage whereby dirt, dust, and similarly small objects may pass underneath when the unit is moved across a surface. The arch 17 thereby eliminates the tendency to scratch the surface and decreases the likelihood of encountering obstacles that could provide lateral resistance and destabilize the unit as it is moved.

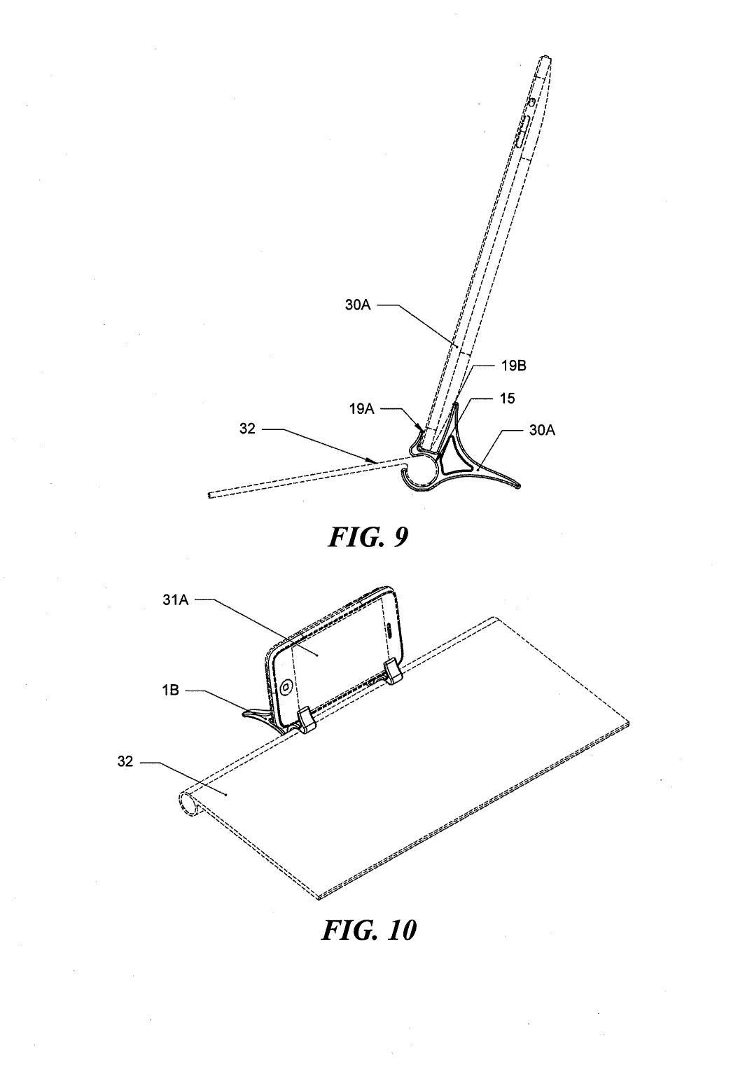

In the space between the bottom arch 17 and the rear support 19b there exists a cavity 16 cut out for material saving purposes. Above the first contact point 12a is a circular cutout 14 that conforms to the shape of a peripheral input device such as a wireless keyboard for connection purposes that are described below with regard to FIG. 9. At the base of the cutout 14 is an additional semicircular cutout 15 wherein material has been removed to better enable attachment of a wireless keyboard or similar device by accounting for any surface irregularities that may exist on the keyboard.

In one embodiment, the length of the stand between 19b and 12b (the rear foot) can be extended to provide greater stability. Alternatively, the distance between the contact points 12a and 12b can be increased by moving the position of the cutout 14 that receives the peripheral device forward. One mechanism for extending the front or rear foot uses a telescoping or pivoting rod. Embodiments of the stand can include a thicker front retaining barrier 19a and rear support 19b to strengthen the unit or thinner elements to minimize the material used to produce the stand.

In one embodiment, the cutout 14 can take on a different shape (e.g., square or rectangular) to accommodate the cross-section of a particular peripheral device to be received by the stand. Additionally, the opening of the cutout 14 can be made larger so that the peripheral device can snap or clip on to the stand, rather than sliding into the stand.

Finally, the shape of the stand can be custom adjusted for aesthetics.

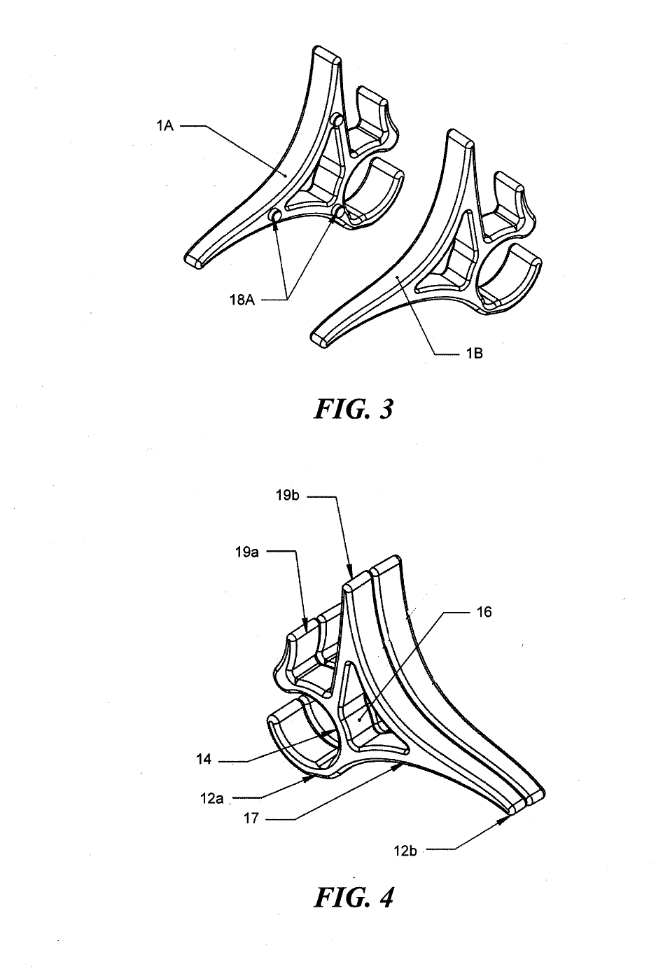

FIG. 2 is a rear, top, right, isometric view of a preferred embodiment, indicating the simultaneous use of two components that, together, constitute a stand for a handheld electronic device. From this angle, both the left component 1B and the right component 1A of the stand are visible. Both components are identical except for a series of protrusions 18A on the innermost side of the right component 1A and a series of holes 18B on the innermost side of the left component 1B. FIG. 3 is a rear, top, left isometric view that illustrates the protrusions 18A on the right side component 1A. These protrusions 18A and their corresponding holes 18B snap together to allow the first and second components of the stand to connect into a single, functioning unit, as depicted in FIG. 4.

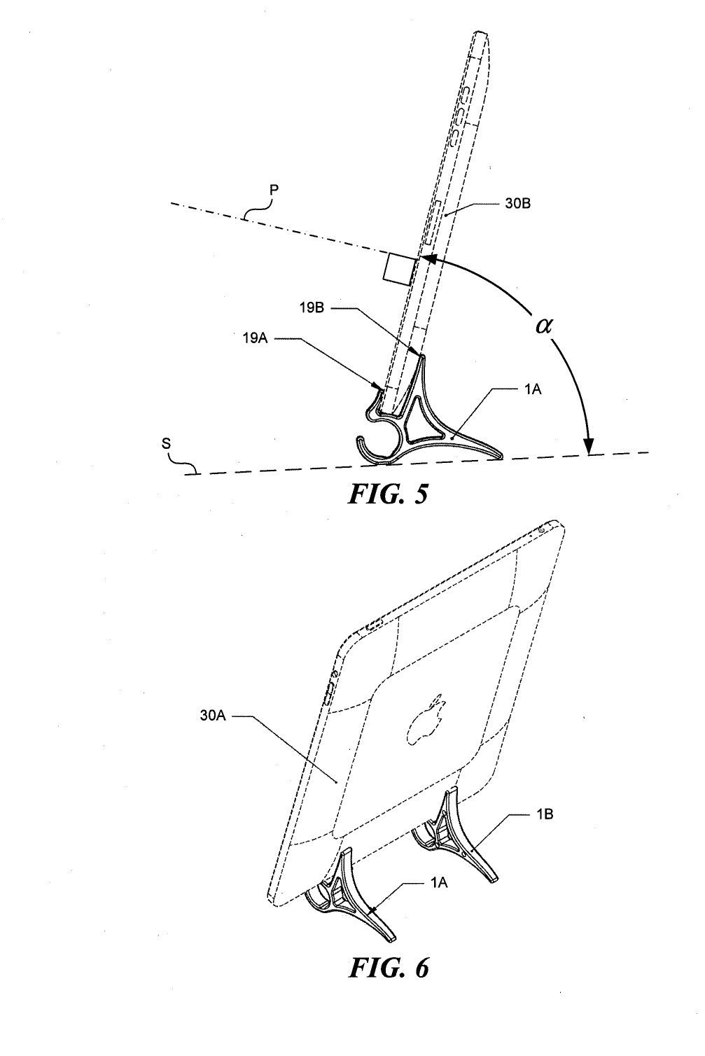

FIG. 5 is a right side view of the stand 1 in use with a handheld electronic device 30B. Despite the thickness of the device 30B, embodiments maintain their functionality as an upright stand by pivoting the front of the device 33 between the front and rear restraining edges, 19a and 19b respectively. Such functionality may be adapted to account for devices of thickness less than or equal to the width of the angled slot into which they fit. In alternative embodiments, the slot width and the position of the pivot points 19a and 19b may be adjusted in a way such that the design is amenable to handheld electronic devices of differing dimensions.

The electronic device stand in accordance with an embodiment of the present invention orients at least one model of an iPad® made by Apple Incorporated of Cupertino, Calif., such that an angle α included between an axis P perpendicular to a generally flat display of the at least one model of an iPad® and the supporting surface has a range between approximately 45° and approximately 80°. In one embodiment, the range is between approximately 60° and approximately 80°. In one embodiment, the angle α is approximately 70°.

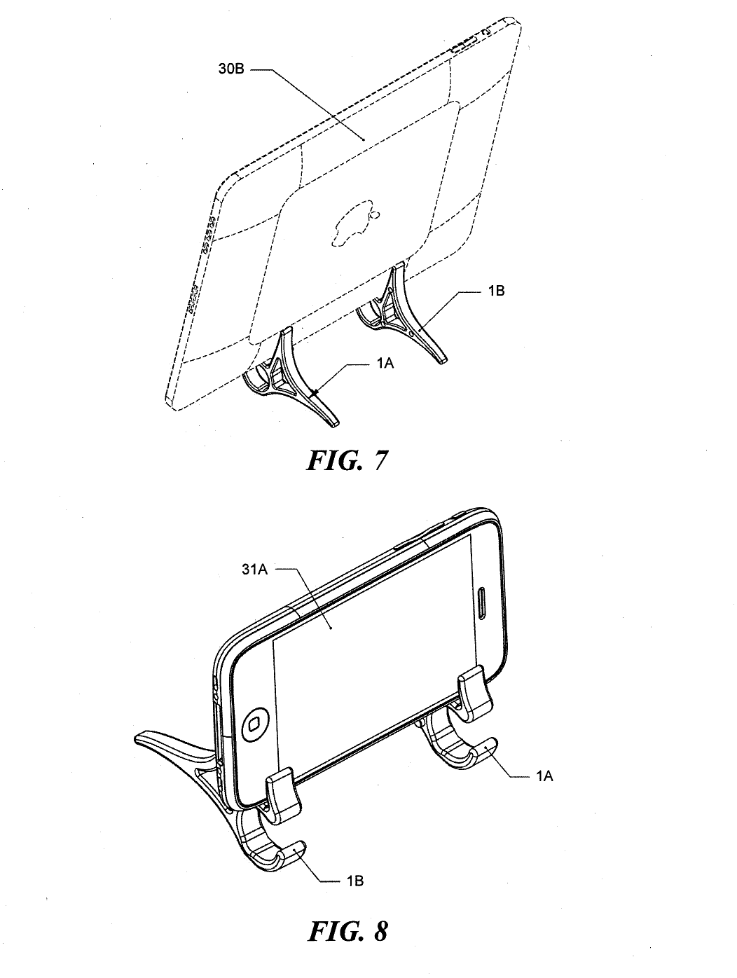

FIG. 6 and FIG. 7 offer rear, top, right isometric views of the stand in use with a handheld electronic device in various device orientations that the stand can accommodate. In FIG. 6 the device 30A is upright in an approximately vertical position. In FIG. 7, the device 30A is supported in the stand on its side. FIG. 8 illustrates the potential to use a different device, such as a cellular phone or smartphone 31A, with the stand according to an embodiment.

FIG. 9 shows an embodiment of the stand with a handheld electronic device 30A and a wireless keyboard 32 coupled thereto. The stand and the keyboard 32 are structurally coupled by means of a circular cutout 15 that rims and elastically fastens to a battery storage chamber of the keyboard 32. The stand can be laterally slid onto the keyboard 32 in order to couple the two and can be easily removed in the same manner.

The circular cutout of the base 15, which attaches to a wireless keyboard, enables the entire unit to be lifted, moved, and manipulated in a fashion such that changes in the position of the keyboard induces a corresponding change in the position of the stand and whatever electronic device may be contained therein. This encompasses sideways movement, as would be the case if the unit were slid across a surface, in addition to vertical movement that may occur if the keyboard is lifted or removed from a surface such as a desktop. The circular cutout of the base 15 enables easy adjustment of the components and the device contained therein 30A relative to the keyboard to which they are attached. Thus the components of the present embodiment can be slid along the length of a keyboard to better adjust for electronic devices of variable dimensions. Further, the nature of the present invention is such that it remains connected to the keyboard 32 even when said keyboard 32 is moved. This allows for easy removal and attachment of electronic devices 30A without disrupting the predetermined arrangement of the components upon the keyboard or other data input device.

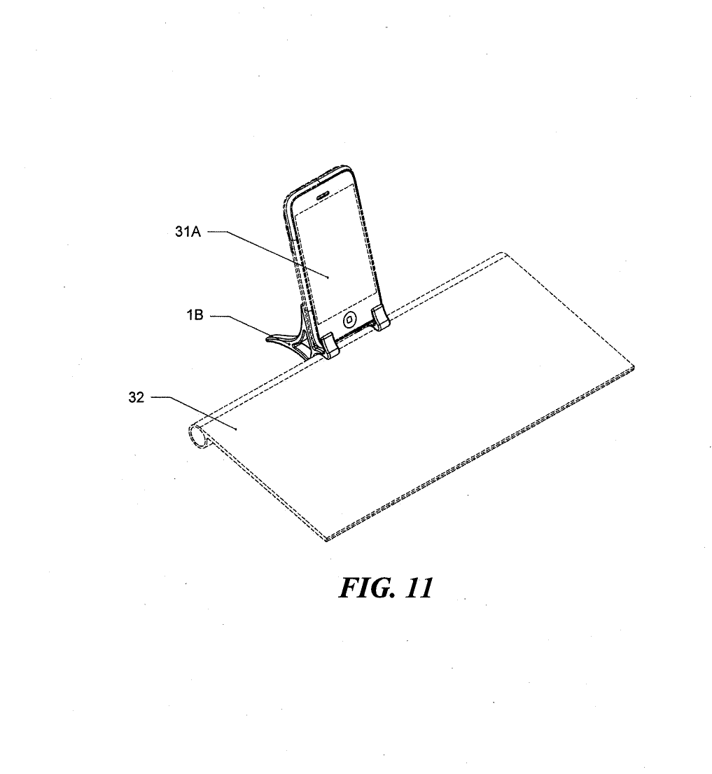

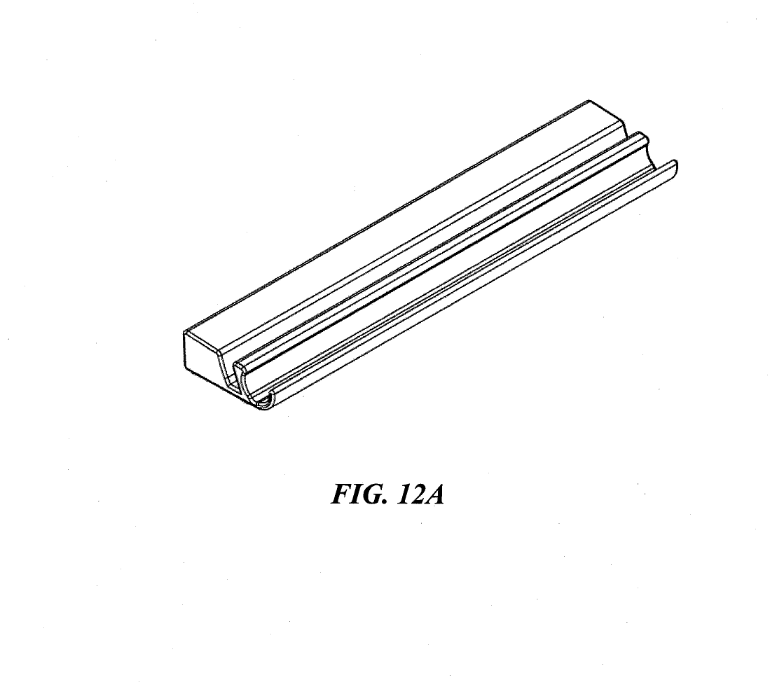

FIGS. 10 and 11 identify this adaptable nature of the present embodiment such that it accounts for devices in different orientations and sizes. FIG. 10 depicts the usage of the present invention attached to a wireless keyboard 31 and with a handheld mobile phone 31A held on its side therein. FIG. 11 similarly identifies the present invention attached to a wireless keyboard 32 but adjusted to accommodate a handheld electronic device 31A placed in an upright position.

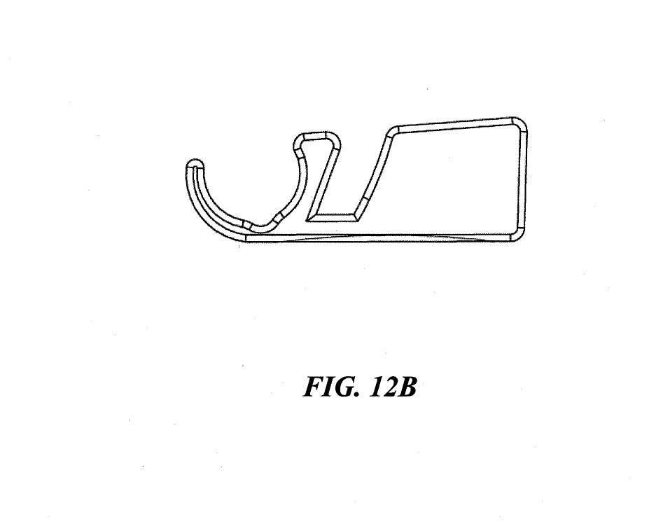

FIGS. 12A and 12B show a perspective view and a side view, respectively, of a stand that is a single elongated unit. The single unit has a slot to receive the electronic device with display and support the display at a suitable angle for a user to view the display and another slot to receive the keyboard to be used with the electronic device.

One embodiment of the present technology acts as an independent stand for an information display and integrated with peripherals such as a data input device based upon the recognition that many electronic devices are most effective when used in an approximately upright position. In the case of tablets and e-readers, many personal computing devices are used most often for information display. In these circumstances, the user is not actively interacting with the device but instead engages passively, as would be the case when reading, viewing, or listening to media.

While the present invention has been disclosed with reference to certain embodiments, numerous modifications, alterations, and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the disclosure is not intended to be exhaustive or to limit the teachings to the precise form disclosed above. While specific embodiments of, and examples for, the disclosure are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or sub-combinations. Each of these processes or blocks may be implemented in a variety of different ways. Also, while processes or blocks are at times shown as being performed in series, these processes or blocks may instead be performed in parallel, or may be performed at different times. Further any specific numbers noted herein are only examples: alternative implementations may employ differing values or ranges.

The teachings of the disclosure provided herein can be applied to other systems, not necessarily the system described above. The elements and acts of the various embodiments described above can be combined to provide further embodiments.

Any patents and applications and other references noted above, including any that may be listed in accompanying filing papers, are incorporated herein by reference. Aspects of the disclosure can be modified, if necessary, to employ the systems, functions, and concepts of the various references described above to provide yet further embodiments of the disclosure.

These and other changes can be made to the disclosure in light of the above Detailed Description. While the above description describes certain embodiments of the disclosure, and describes the best mode contemplated, no matter how detailed the above appears in text, the teachings can be practiced in many ways. Details of the system may vary considerably in its implementation details, while still being encompassed by the subject matter disclosed herein. As noted above, particular terminology used when describing certain features or aspects of the disclosure should not be taken to imply that the terminology is being redefined herein to be restricted to any specific characteristics, features, or aspects of the disclosure with which that terminology is associated. In general, the terms used in the following claims should not be construed to limit the disclosure to the specific embodiments disclosed in the specification, unless the above Detailed Description section explicitly defines such terms. Accordingly, the actual scope of the disclosure encompasses not only the disclosed embodiments, but also all equivalent ways of practicing or implementing the disclosure under the claims.

While certain aspects of the disclosure are presented below in certain claim forms, the inventors contemplate the various aspects of the disclosure in any number of claim forms. For example, while only one aspect of the disclosure is recited as a means-plus-function claim under 35 U.S.C. §112, ¶6, other aspects may likewise be embodied as a means-plus-function claim, or in other forms, such as being embodied in a computer-readable medium. (Any claims intended to be treated under 35 U.S.C. §112, ¶6 will begin with the words “means for.”) Accordingly, the applicant reserves the right to add additional claims after filing the application to pursue such additional claim forms for other aspects of the disclosure.

What is claimed is:

1. An apparatus configured to:
receive in a slot an edge of a handheld device and support the handheld device on a surface in a viewing position suitable for viewing a display of the handheld device; and
receive an input device for the handheld device and hold the input device on the surface in a working position, wherein the working position is suitable for using the input device.

2. The apparatus of claim 1, wherein the apparatus comprises two or more holders, and further wherein the two or more holders are not coupled when supporting the handheld device.

3. The apparatus of claim 2, wherein one or more spacings between the two or more holders is adjustable by a user.

4. The apparatus of claim 2, wherein the two or more holders include a coupling mechanism to couple the holders together when not in use.

5. The apparatus of claim 4, wherein the coupling mechanism comprises one or more protrusions from a first one of the holders and one or more holes in a second one of the holders to snap the one or more protrusions into.

6. The apparatus of claim 1, wherein a position of the handheld device relative to the input device is adjustable by a user.

7. The apparatus of claim 1, wherein the input device can be snapped or slid into the receiving slot.

8. The apparatus of claim 1, wherein the handheld device is a portable electronic device selected from one of the following: a cell phone, a smartphone, or an electronic tablet device.

9. The apparatus of claim 1, wherein the apparatus is tapered to have a wider front and a narrower back for stability.

10. The apparatus of claim 1, wherein a plurality of widths of the edge of the handheld device can be received by the apparatus.

11. The apparatus of claim 1, wherein a base of the apparatus contacts the surface, and further wherein a dimension of the base is adjustable to provide stability to the apparatus.

12. The apparatus of claim 1, wherein the slot is designed to fit a specific handheld device.

13. The apparatus of claim 1, wherein the apparatus further comprises an electrical component configured to provide an electrical coupling between the handheld device and the input device.

14. The apparatus of claim 13, wherein the electrical component comprises one or more wires or cables, and the electrical component is housed at least partially within the apparatus.

15. The apparatus of claim 13, wherein the electrical component comprises one or more wires or cables, the electrical component is external to the apparatus, and the electrical component is physically coupled to the apparatus through an attachment mechanism.

16. The apparatus of claim 13, wherein the electronic component is used to charge the handheld device.

17. The apparatus of claim 1, wherein the apparatus includes one or more slip resistant elements to prevent the apparatus from moving relative to at least one of: the handheld unit, the input device, or the surface.

18. The apparatus of claim 1, wherein the apparatus is integrated into a storage mechanism.

19. The apparatus of claim 1, wherein the input device is a part of the apparatus.

20. A first apparatus for supporting a handheld device on a surface, the first apparatus comprising:
a first body;
a first device support portion coupled to the first body and configured to receive an edge of the handheld device on a first seat portion between a first front arm and a first back arm, wherein the handheld device is supported on a display side of the handheld device by the first front arm and on a back side of the handheld device by the first back arm;
a first front support member coupled to the first body and configured to engage the surface, wherein the first front support member has a suitable shape to receive the input device for the handheld device;
a first back support member coupled to the first body, the first back arm, and the first front support member, wherein the first back support member is configured to engage the surface.

21. The first apparatus of claim 20, wherein the first apparatus is used with a second apparatus, and the second apparatus comprises:
a second body;
a second device support portion coupled to the second body and configured to receive an edge of the handheld device on a second seat portion between a second front arm and a second back arm, wherein the handheld device is supported on the display side of the handheld device by the second front arm and on the back side of the handheld device by the second back arm;
a second front support member coupled to the second body and configured to engage the surface, wherein the second front support member has a suitable shape to receive the input device for the handheld device;
a second back support member coupled to the second body, the second back arm, and the second front support member, wherein the second back support member is configured to engage the surface,
wherein the first apparatus and the second apparatus are configured to be used together to support the handheld device in a suitable position for a user to view the display of the handheld device, and
further wherein the first apparatus and second apparatus are not coupled when supporting the handheld device.

22. The apparatus of claim 21, wherein the first apparatus and the second apparatus have a coupling to secure the first apparatus to the second apparatus.

23. The apparatus of claim 20, wherein the first front support member is configured to have a curved shape that curves upwardly to receive the input device within the curved shape and hold the input device in a fixed position relative to the handheld device.

24. The apparatus of claim 20, wherein the first body between the first back support member and the first front support member is curved concave downwards.

25. The apparatus of claim 20, wherein the first front support member is wider than the first back support member.

26. The apparatus of claim 20, wherein the first body is tapered down from a front of the first body at the first device support portion to a back of the first body at the first back support member.

27. The apparatus of claim 20, wherein the first front arm and the first back arm are angled from vertical such that the display of the device is angled from vertical.

28. The apparatus of claim 20, wherein the first body has an aperture.

29. A pair of holders, each comprising:
means for receiving an edge of a handheld device; and
means for receiving an input device for the handheld device,
wherein the pair of holders together support the handheld device in a viewing position suitable for viewing a display of the handheld device and together hold the input device in a fixed position relative to the handheld device, wherein the fixed position is suitable for using the input device,
wherein the pair of holders are not coupled when supporting the handheld device.
